(19) United States
(12) Patent Application Publication
(10) Pub. No.: US 2016/0214854 A1
(43) Pub. Date: Jul. 28, 2016

(54) MEMS SENSOR

(71) Applicant: SAMSUNG ELECTRO-MECHANICS CO., LTD., Suwon-si (KR)

(72) Inventors: Jong Woon KIM, Suwon-si (KR); Tae Yoon KIM, Suwon-si (KR); Dae Hun JEONG, Suwon-si (KR)

(73) Assignee: SAMSUNG ELECTRO-MECHANICS CO., LTD., Suwon-si (KR)

(21) Appl. No.: 15/003,099

(22) Filed: Jan. 21, 2016

(30) Foreign Application Priority Data
Jan. 23, 2015 (KR) 10-2015-0011421

(51) Int. Cl. B81B 3/00

(52) U.S. Cl. CPC B81B 3/0078; B81B 2203/0127

(57) ABSTRACT

A microelectromechanical systems (MEMS) sensor includes a first layer on which a first displacement limiting part and a second displacement limiting part are formed; a third layer on which a mass body part and a support part are formed; and a second layer connecting the first layer and the third layer to each other, wherein at least a portion of the first displacement limiting part is directly opposed to the mass body part, and at least a portion of the second displacement limiting part is directly opposed to the support part.

### CROSS-REFERENCE TO RELATED APPLICATION

This application claims the priority and benefit of Korean Patent Application No. 10-2015-0011421 filed on Jan. 23, 2015, with the Korean Intellectual Property Office, the disclosure of which is incorporated herein by reference.

### BACKGROUND

The present disclosure relates to a microelectromechanical systems (MEMS) sensor.

Generally, inertial sensors have been variously used in automobiles, aircraft, mobile communications terminals, toys, and the like, and three-axis acceleration and angular velocity sensors measuring acceleration and angular velocity on an X-axis, a Y-axis, and a Z-axis have been demanded and have been developed to have high performance and a small size in order to finely detect acceleration.

Among the inertial sensors as described above, an acceleration sensor has a technical feature of converting movements of a mass body and a flexible beam into an electrical signal, and examples of acceleration sensors include a piezoresistive-type acceleration sensor detecting the movement of the mass body from a change in resistance of a piezoresistive element disposed on the flexible beam and a capacitive-type acceleration sensor detecting movement of the mass body from a change in capacitance between the mass body and a fixed electrode.

In addition, the piezoresistive-type acceleration sensor uses an element of which a resistance value is changed by stress, and for example, the resistance value may be increased in a location in which tensile stress is distributed and the resistance value is decreased in a location in which compressive stress is distributed.

In addition, a mobile device on which the acceleration sensor is mounted has a pressure sensor, an MIC, and the like mounted together thereon, and it is important for components of mobile devices to be miniaturized. Therefore, it is necessary to implement miniaturization by integrating a variety of sensors into a single sensor or a single package.

### SUMMARY

An aspect of the present disclosure may provide a microelectromechanical systems (MEMS) sensor allowing for improved productivity and device thinning by deforming a shape of a membrane without using separate stoppers such as an upper cap to implement upward and downward stoppers and a lower cap, and improving reliability against impacts as rigidity of the stoppers can be freely designed.

According to an aspect of the present disclosure, a microelectromechanical systems (MEMS) sensor may include a first layer on which a first displacement limiting part and a second displacement limiting part are formed; a third layer on which a mass body part and a support part are formed; and a second layer connecting the first layer and the third layer to each other, wherein at least a portion of the first displacement limiting part is directly opposed to the mass body part, and at least a portion of the second displacement limiting part is directly opposed to the support part.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view schematically illustrating a microelectromechanical systems (MEMS) sensor according to an exemplary embodiment in the present disclosure;

FIG. 2 is a schematic cross-sectional view taken along line I-I′ of the MEMS sensor according to an exemplary embodiment in the present disclosure;

FIG. 3A is a schematic plan view of a first layer in the MEMS sensor illustrated in FIG. 1;

FIG. 3B is a schematic plan view of a second layer in the MEMS sensor illustrated in FIG. 1;

FIG. 3C is a schematic plan view of a third layer in the MEMS sensor illustrated in FIG. 1; and

FIGS. 4A and 4B are usage state diagrams of the MEMS sensor according to an exemplary embodiment in the present disclosure.

### DETAILED DESCRIPTION

Hereinafter, embodiments of the present inventive concept will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate) , is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present inventive concept will be described with reference to schematic views illustrating embodiments of the present inventive concept. In the drawings, for example, due to manufacturing techniques and/or tolerances, modifications of the shape shown may be estimated. Thus, embodiments of the present inventive concept should not be construed as being limited to the particular shapes of regions shown herein, for example, to include a change in shape results in manufacturing. The following embodiments may also be constituted by one or a combination thereof.

The contents of the present inventive concept described below may have a variety of configurations and propose only a required configuration herein, but are not limited thereto.

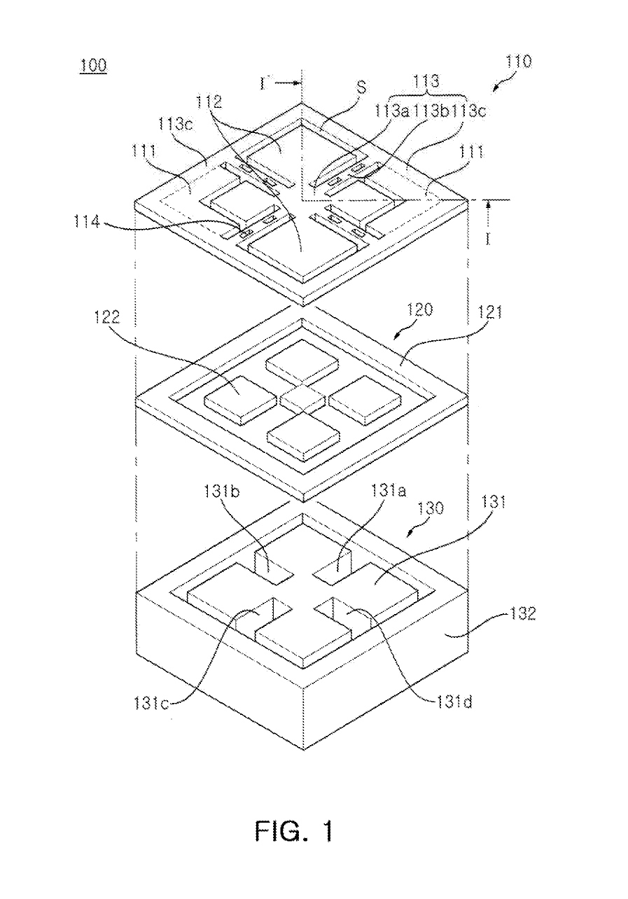

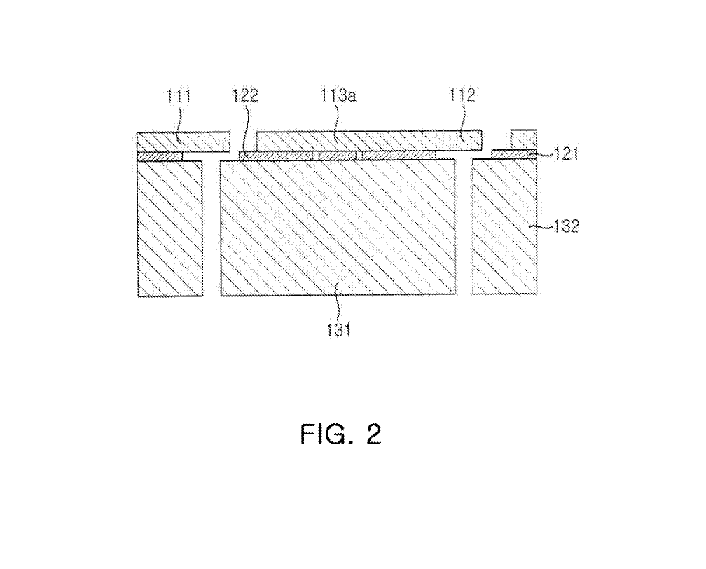

FIG. 1 is an exploded perspective view schematically illustrating a microelectromechanical systems (MEMS) sensor according to an exemplary embodiment in the present disclosure and FIG. 2 is a schematic cross-sectional view taken along line I-I′ of the MEMS sensor according to an exemplary embodiment in the present disclosure.

As illustrated, the MEMS sensor 100 may include a first layer 110, a second layer 120, and a third layer 130, wherein the first layer 110 may have a first displacement limiting part and a second displacement limiting part formed thereon, which are stoppers, the second layer 120 may be a bonding part connecting the first layer 110 and the third layer 130 to each other, and the third layer 130 may include a mass body part 131 and a support part 132.

Further, the MEMS sensor 100 may include a sensing unit and a driving unit so as to be implemented as an acceleration sensor or an angular velocity sensor. To this end, the first layer 110 may have an electrode part formed thereon. Further, the electrode part may be implemented as at least one of an excitation electrode and a sensing electrode.

More specifically, the first layer 110, a membrane layer, may have an upward displacement limiting part 111, the first displacement limiting part, a downward displacement limiting part 112, the second displacement limiting part, and a beam part 113 all of which are formed thereon.

Further, at least a portion of the upward displacement limiting part 111 may be positioned to be opposed to the mass body part 131 of the third layer 130. This is to allow the mass body part 131 to be in contact with the upward displacement limiting part 111 when excessive displacement of the mass body part 131 occurs in an upward direction to prevent additional displacement.

Further, at least a portion of the downward displacement limiting part 112 may be positioned to be opposed to the support part 132 of the third layer 130. This is to allow the downward displacement limiting part 112 to descend together with the mass body and to be in contact with the support part 132 when excessive displacement of the mass body part 131 occurs in a downward direction to prevent additional displacement.

As a result, as illustrated in FIG. 2, at least a portion of the upward displacement limiting part 111 may not be opposed to a second bonding part 122 of the second layer 120 and may be directly opposed to the mass body part 131, and at least a portion of the downward displacement limiting part 112 may not be opposed to a first bonding part 121 of the second layer 120 and may be directly opposed to the support part 132.

Further, the beam part 113 may include a central portion 113a, a displacement portion 113b, and a frame portion 113c.

Further, the downward displacement limiting part 112 may be connected to the central portion 113a, and bending stress or tensile stress may occur from the displacement portion 113b, depending on displacement of the mass body part 131. Further, the displacement portion 113b may be provided with an electrode 114 for detecting acceleration or angular velocity. Further, the electrode 114 may be formed of an excitation electrode or a sensing electrode.

Further, the frame portion 113c may be formed as a frame of the first layer 121.

Further, the upward displacement limiting part 111 may be formed to be connected to the frame portion 113c and to be extended toward the central portion 113a.

Further, one end of the displacement portion 113b may be connected to the central portion 113a, and the other end thereof may be connected to the frame portion 113c.

Further, the upward displacement limiting part 111 and the downward displacement limiting part 112 may be formed in pairs which are diagonally opposed to each other. That is, the upward displacement limiting part 111 and the downward displacement limiting part 112 may each be disposed at both sides based on the displacement portion 113b.

In addition, the above-mentioned arrangement of the upward displacement limiting part 111 and the downward displacement limiting part 112 is to limit excessive displacement of the mass body part 131 even in a case in which excessive displacement of the mass body part 131 occurs in the upward direction and the downward direction simultaneously with rotational displacement thereof.

In addition, the upward displacement limiting part 111 and the downward displacement limiting part 112 may be formed to be connected to the frame portion 113c and the central portion 113a, respectively.

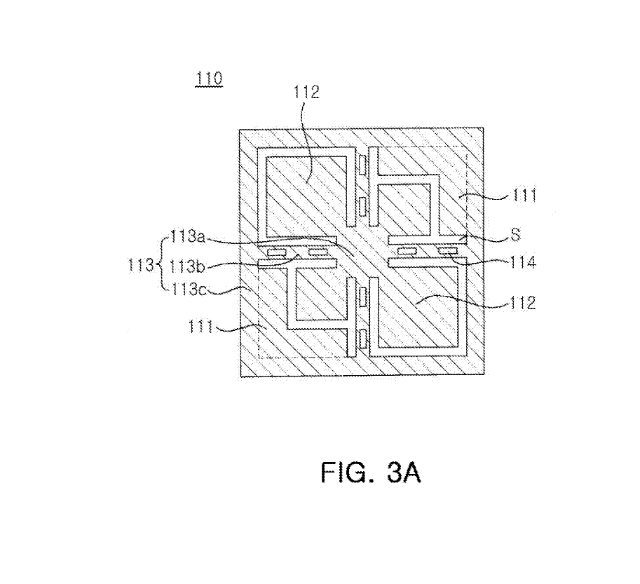

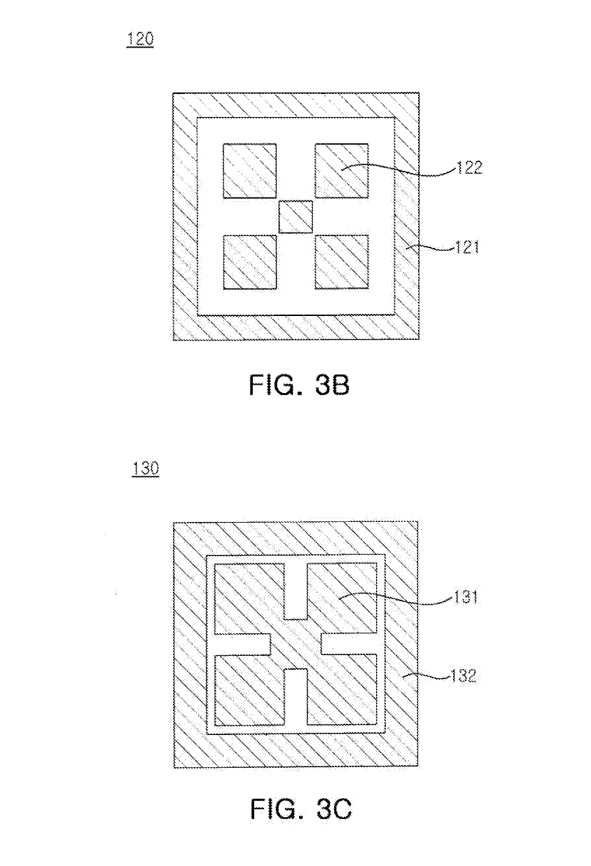

In addition, the first layer 110 may be provided with a slit S, a penetrating part, so that the upward displacement limiting part 111, the downward displacement limiting part 112, and the beam part 113 are formed, as illustrated in FIG. 3A.

Next, the second layer 120 may be the bonding part for coupling the first layer 110 and the third layer 130 to each other as described above, and may include the first bonding part 121 coupled to the support part 132 of the third layer 130, and the second bonding part 122 coupled to the mass body part 131 of the third layer 130.

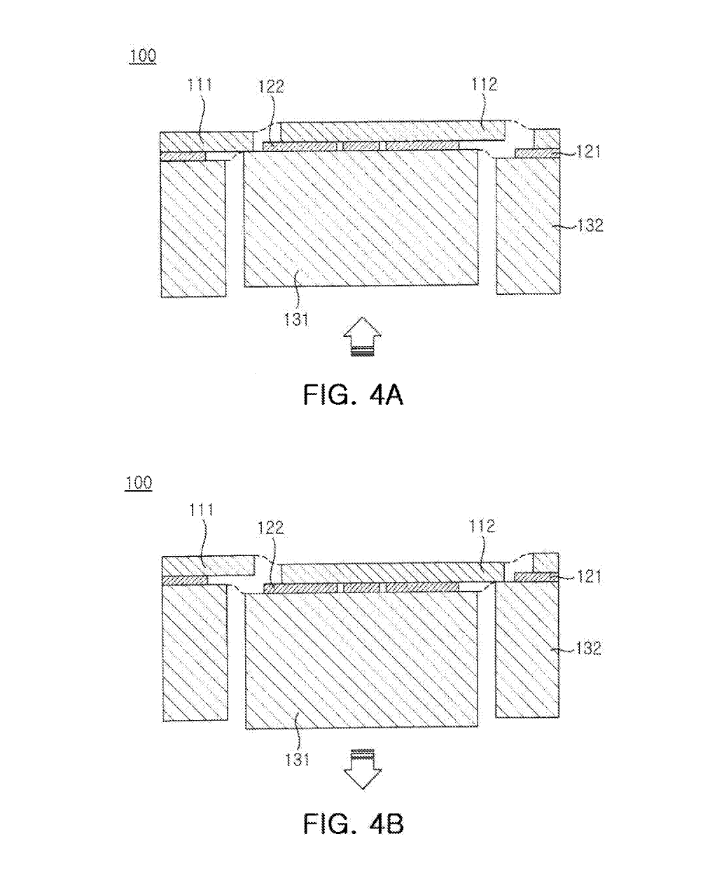

In addition, as illustrated in FIG. 2, the first bonding part 121 may be formed to have an area smaller than that of the support part 132 coupled thereto, in relation to an area in which the second layer 120 and the third layer 130 are in contact with each other. Further, this is to allow the downward displacement limiting part 112 to be in contact with the support part 132 when excessive displacement of the mass body part 131 occurs in the downward direction, as illustrated in FIG. 4B.

Further, as illustrated in FIG. 2, the second bonding part 122 may be formed to have an area smaller than that of the mass body part 131 coupled thereto, in relation to the area in which the second layer 120 and the third layer 130 are in contact with each other. Further, this is to allow the mass body part 131 to be in contact with the upward displacement limiting part 111 when excessive displacement of the mass body part 131 occurs in the upward direction, as illustrated in FIG. 4A.

Next, the third layer 130 may include the mass body part 131 and the support part 132. Further, the mass body part 131 may be displaced by inertial force, external force, Coriolis force, driving force, and the like, and may be displaceably coupled to the first layer 110 by the second bonding part 122 of the second layer 120.

In addition, the mass body part 131 may be provided with four groove parts 131a, 131b, 131c, and 131d externally penetrating through the mass body part 131 from a center portion thereof at equidistant intervals, and may be generally formed to have a rectangular parallelepiped shape.

In addition, the support part 132 may be coupled to the first layer 110 by the first bonding part 121 of the second layer 120, and may displaceably support the mass body part 131.

FIGS. 4A and 4B are usage state diagrams of the MEMS sensor according to an exemplary embodiment in the present disclosure. As illustrated in FIG. 4A, when excessive displacement of the mass body part 131 of the MEMS sensor 100 occurs in one direction, that is, displacement occurs in the upward direction, one end portion of the mass body part 131 may be in contact with the upward displacement limiting part 111 and upward displacement may be limited.

In addition, since FIG. 4A is illustrated based on the cross-sectional view taken along line I-I′ illustrated in FIG. 2, the upward displacement of both sides of the mass body part 131 may be limited by the upward displacement limiting part 111.

Next, as illustrated in FIG. 4B, when excessive displacement of the mass body part 131 of the MEMS sensor 100 in the other direction, that is, displacement occurs in the downward direction, the downward displacement limiting part 112 may be in contact with the support part 132 of the third layer 130 and downward displacement may be limited.

In addition, since FIG. 4B is illustrated based on the cross-sectional view taken along line I-I′ illustrated in FIG. 2, the downward displacement of both sides of the downward displacement limiting part 112 may be actually limited by the support part 132.

As described above, the MEMS sensor according to an exemplary embodiment in the present disclosure may include the first layer, the second layer, and the third layer, wherein productivity may be improved and thinness may be implemented by deforming a shape of the first layer to implement stoppers limiting the upward and downward displacements, and reliability against impacts may be improved as rigidity of the stoppers can be freely designed.

While exemplary embodiments have been shown and described above, it will be apparent to those skilled in the art that modifications and variations could be made without departing from the scope of the present invention as defined by the appended claims.

What is claimed is:

1. A microelectromechanical systems (MEMS) sensor comprising:
a first layer on which a first displacement limiting part and a second displacement limiting part are formed;
a third layer on which a mass body part and a support part are formed; and
a second layer connecting the first layer and the third layer to each other,
wherein at least a portion of the first displacement limiting part is directly opposed to the mass body part, and
at least a portion of the second displacement limiting part is directly opposed to the support part.

2. The MEMS sensor of claim 1, wherein the first displacement limiting part of the first layer is an upward displacement limiting part limiting upward displacement for a displacement direction of the mass body part, and
the second displacement limiting part is downward displacement limiting part limiting downward displacement for the displacement direction of the mass body part.

3. The MEMS sensor of claim 2, wherein the first layer includes the upward displacement limiting part, the downward displacement limiting part, and a beam part,
the beam part includes a central portion, a displacement portion, and a frame portion,
the central portion is connected to the downward displacement limiting part,
bending or tensile stress occurs from the displacement portion depending on a displacement of the mass body part, and
the frame portion is formed as a frame of the first layer.

4. The MEMS sensor of claim 3, wherein the upward displacement limiting part is formed to be connected to the frame portion and to be extended toward the central portion.

5. The MEMS sensor of claim 3, wherein the displacement portion is formed of at least one of an excitation electrode and a sensing electrode.

6. The MEMS sensor of claim 3, wherein one end portion of the displacement portion is connected to the central portion, and the other end portion thereof is connected to the frame portion.

7. The MEMS sensor of claim 1, wherein the second layer includes a first bonding part coupled to the support part of the third layer and a second bonding part coupled to the mass body part of the third layer.

8. The MEMS sensor of claim 7, wherein the first bonding part is formed to have an area smaller than that of the support part, in relation to an area in which the second layer is coupled to the third layer.

9. The MEMS sensor of claim 7, wherein the second bonding part is formed to have an area smaller than that of the mass body part, based on an area in which the second layer is coupled to the third layer.

10. The MEMS sensor of claim 2, wherein when excessive displacement of the mass body part occurs in an upward direction, the mass body part is in contact with the upward displacement limiting part of the first layer.

11. The MEMS sensor of claim 2, wherein when excessive displacement of the mass body part occurs in a downward direction, the downward displacement limiting part of the first layer is in contact with the support part.
